(19) United States
(12) Patent Application Publication
(10) Pub. No.: US 2016/0211396 A1
(43) Pub. Date: Jul. 21, 2016

(54) SEMITRANSPARENT PHOTOVOLTAIC MODULE AND CORRESPONDING MANUFACTURING PROCESS

(71) Applicants: COMMISSARIAT A L'ENERGIE ATOMIQUE ET AUX ENERGIES ALTERNATIVES, Paris (FR); CROSSLUX, Rousset (FR)

(72) Inventors: Nicolas Karst, Folkling (FR); Pascal Faucherand, Sassenage (FR); Simon Perraud, Bandol (FR); Frédéric Roux, Saint-Égrève (FR); Pierre-Yves Thoulon, Le Tholonet (FR)

(73) Assignees: COMMISSARIAT A L'ENERGIE ATOMIQUE ET AUX ENERGIES ALTERNATIVES, Paris (FR); CROSSLUX, Rousset (FR)

(21) Appl. No.: 14/914,507

(22) PCT Filed: Sep. 4, 2014
(86) PCT No.: PCT/IB2014/064254

§ 371 Date: Feb. 25, 2016

(30) Foreign Application Priority Data
Sep. 5, 2013 (FR) 1358509

(51) Int. Cl. H01L 31/0468; H01L 31/0465

(52) U.S. Cl. CPC H01L 31/0468; H01L 31/0465

(57) ABSTRACT

The invention relates to a photovoltaic module comprising a plurality of photovoltaic cells in a structure made up of thin films, comprising the following steps: a step of producing an intermediate product by depositing on the entirety of a substrate a layer of a conductive material, forming an absorbing layer on this layer of a conductive material, and producing holes through the stack formed by the layer of a conductive material and the absorbing layer, the layer of a conductive material forming the backside electrode; a step of depositing a transparent insulating material in the holes of the intermediate product, the absorbing layer being devoid of this material; and a step of depositing a layer forming the front side electrode, on the entirety of the product obtained.

The invention relates to the technical field of photovoltaic solar energy, and more particularly thin layer photovoltaic modules.

In the context of the present invention, a “thin layer” will be a layer having a thickness smaller than 5 μm.

In order to facilitate the integration of photovoltaic panels into buildings and optimize the surface area that they occupy, it is desirable to have partially transparent photovoltaic panels. Indeed, they can then replace part of the window of the building in which they are integrated.

A photovoltaic module traditionally includes several photovoltaic cells placed in series.

A thin layer photovoltaic cell is structured in a stack successively comprising a transparent or nontransparent substrate, a backside electrode (for example made from metal or a conductive transparent oxide), a layer of absorbent material (for example, a layer of CIGS, CZTS, hydrogenated amorphous silicon, hydrogenated microcrystalline silicon, cadmium tellurium), and lastly a front side electrode (for example made from metal or a conductive transparent oxide). In particular in the case of an absorber made from CIGS or CZTS, a buffer layer can be used between the absorber and the front side electrode.

Furthermore, several photovoltaic cells can be placed in series through etching and deposition steps done on a same substrate. This monolithic interconnection of the thin layer photovoltaic cells is done in three steps, traditionally called P1, P2 and P3.

The first step (P1) ensures the electrical insulation of two adjacent cells at the backside electrode of the photovoltaic cells.

The second step (P2) makes it possible to connect the front side electrode of a given cell to the backside electrode of the adjacent cell.

The third step (P3) consists of electrically insulating two adjacent cells at the front side electrode.

Several solutions have already been proposed to produce a semitransparent photovoltaic cell or a semitransparent photovoltaic module.

Thus, document US 2010/0126559 describes a photovoltaic module of the superstrate type, in which the substrate and the backside electrode are transparent. Furthermore, the opening obtained during the etching step P3 has a width adapted to the desired transparency for the final photovoltaic module. This opening is made through the absorbing layer and the front side electrode. This width can for example vary between 5 and 10% of the width of a photovoltaic cell.

Generally, the photovoltaic module obtained can transmit between about 5 and 50% of the incident light.

This solution nevertheless has drawbacks.

In particular, the openings made in the photovoltaic module are in line form. They are then relatively visible and do not allow a uniform transmission of light. Indeed, in order for the light to be transmitted uniformly and the assembly of the module to appear partially transparent, it is necessary for the structures allowing light to pass to be indiscernible.

Document GB-2472608 proposes producing a semitransparent photovoltaic cell from a stack comprising a transparent substrate and backside electrode and an opaque absorbing layer and front side electrode.

Small holes are formed through the opaque front side electrode and active layer, so as to allow the transmission of light through these holes.

These holes are obtained by wet etching operations. Thus, an etching liquid is deposited on the surface of the photovoltaic cells by means of an inkjet head, so as to allow localized etching of at least the first layer of the stack.

The stack being made up of layers of materials having different chemical natures, it is necessary to use different successive etching liquids to allow the formation of holes over the desired depth.

The method described in this document makes it possible to avoid the formation of lines that are easily visible.

However, the use of different etching liquids makes this method relatively complex. Compatibility problems between the materials of the stack and the etching liquids used can also occur.

Document U.S. Pat. No. 7,795,067 describes semitransparent photovoltaic cells that are also obtained from a stack of layers in which a plurality of holes is made.

Unlike the cells described in document GB-2,472,608, these holes cross all the way through the stack.

They can be made using mechanical means, for example by drilling or cutting.

These mechanical methods have the drawback, like most methods involving removing material, of causing the formation of localized short-circuits, due to the presence of material residues within the holes or the formation of “flaps” of material that are not completely detached and that produce and electric bridge (in the case of electrically conductive materials such as molybdenum or conductive transparent oxide) between the upper electrode and the lower electrode, for example.

The invention aims to resolve these drawbacks by proposing a method for obtaining a semitransparent photovoltaic module that is easier to produce while making it possible to obtain a photovoltaic module ensuring a uniform transmission of light and continuous viewing, without risk of short-circuits.

The invention also relates to a method for obtaining a photovoltaic module including a plurality of photovoltaic cells in a thin layer structure, comprising the following steps:
a step for producing an intermediate product by depositing a layer of a conductive material on the entirety of a substrate, forming an absorbing layer on this layer of conductive material, and producing holes through the stack formed by the layer of conductive material and the absorbing layer, the layer of conducting material forming the backside electrode,
a step for depositing an insulating transparent material in the holes of the intermediate product, the absorbing layer not having this material, and
a step for depositing a layer forming the front side electrode on the entirety of the obtained product.

Preferably, the holes have a section with a surface area comprised between 0.005 mm² and 0.2 mm², and the total surface area occupied by the holes is comprised between 5% and 95% of the total surface area of the substrate.

These holes can be made using a mechanical method (in particular drilling) or a chemical method (in particular chemical etching, possibly involving the use of a mask), or through any other method.

Preferably, the step for depositing an insulating and transparent material in the holes of the intermediate product comprises the following operations:
depositing a resin on the entirety of the substrate to cover the absorbing layer and fill in the holes of the intermediate product,
cross-linking the resin present in the holes, and
eliminating the non-cross-linked resin present on the absorbing layer.

Advantageously, the resin is a negative photoresist resin that is first subjected to an annealing step before being exposed through the substrate, the layer of conductive material forming a mask.

Alternatively, the method comprises a step for depositing a buffer layer before depositing the layer forming the front side electrode.

After depositing a layer forming the front side electrode and any buffer layer, the cross-linked resin can be eliminated through the action of a solvent.

The invention also relates to a semitransparent photovoltaic module comprising a plurality of photovoltaic cells connected in series on a shared substrate and comprising a front side electrode and a backside electrode, in contact with said substrate and spaced away from the front side electrode by at least one absorbing layer, in which the stack formed by the backside electrode and the absorbing layer comprises zones that are either empty, or made from an insulating and transparent material, the front side electrode forming a continuous layer.

Preferably, the insulating material is a cross-linked transparent resin. These zones have a section whereof the surface area is comprised between 0.005 mm² and 0.2 mm², and represent between about 5% and 95% of the total surface area of the substrate.

The module can also comprise a buffer layer between the absorbing layer and front side electrode.

In one embodiment, the buffer layer is a continuous layer.

Lastly, the backside electrode is made from a metal material, in particular molybdenum, or from a conductive transparent oxide, in particular an aluminum-doped zinc oxide, or any other conductive material.

The invention also relates to an intermediate product for obtaining a photovoltaic module according to the invention, made up, on a substrate, of a stack formed by a layer of conductive material and an absorbing layer and that includes holes crossing through it.

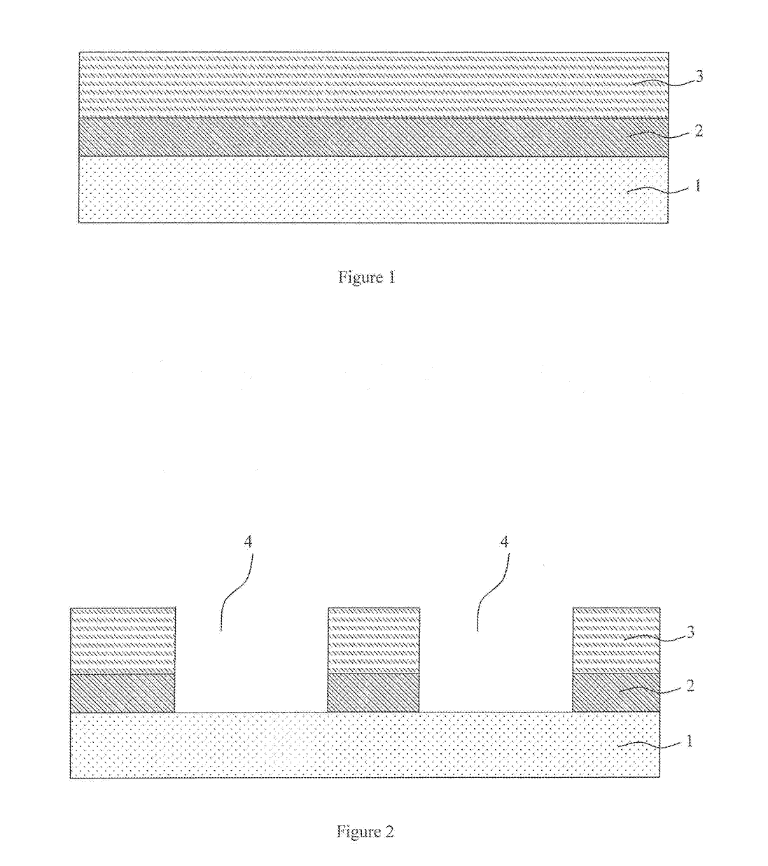

The invention will be better understood and other aims, advantages and features thereof will appear more clearly upon reading the following description that is done in light of the appended drawings, in which FIGS. 1 to 7 show different steps of the implementation of the method according to the invention.

All of these figures are sectional views, and the elements shared by the different figures will be designated using the same references. They do not precisely illustrate the relative thickness of the different depicted layers.

FIG. 1 shows a substrate 1 that can be made from various transparent materials, traditionally from glass or polymer.

The substrate 1 can be flexible or rigid.

In general, this substrate is made from soda-lime glass, the thickness of which is several millimeters, and in particular comprised between 1 and 4 mm.

Deposited on the substrate 1 is a layer of conductive material 2 forming a backside electrode for the different cells of the photovoltaic module that will be obtained using the method according to the invention.

This layer is for example made from a metal material, and in particular molybdenum, and its thickness is comprised between 100 nm and 2 μm, and in particular equal to 1 μm.

The layer of molybdenum can in particular be deposited by cathode sputtering.

This layer 2 can also be made from a conductive transparent oxide, in particular an aluminum-doped zinc oxide.

An absorbing layer 3 is formed on this layer 2. This absorbing layer can be a layer of CIGS, CZTS, hydrogenated amorphous silicon, hydrogenated monocrystalline silicon, cadmium tellurium. The thickness of this absorbing layer is typically comprised between 100 nm and 5 μm.

Preferably, this absorbing layer is a thin layer of CIGS or CZTS, with a thickness comprised between 1 μm and 2 μm. In this case, this absorbing layer can be formed by deposition by co-evaporation from elementary sources, or by a sequential method, as is well known in the field of CIGS or CZTS thin layer photovoltaic cells.

In the case of a sequential method, the precursors that lead to the formation of the CIGS or CZTS absorbing layer are contributed on the layer 2, in the form of a layer. The precursors are preferably metals (Cu, In, Ga in the case of CIGS; Cu, Zn, Sn in the case of CZTS), but can also be compounds of metals and selenium, or compounds of metals and sulfur. A thin layer of selenium or sulfur can be deposited on the layer of precursors.

These precursors can be contributed by different deposition methods. This may involve a vacuum method, such as evaporation or cathode sputtering, or a non-vacuum method, such as doctor blading, spin coating, screen printing or electrodeposition.

At least one annealing step is carried out so as to convert the precursors into an absorbing material, of the CIGS or CZTS type, owing to the contribution of selenium or sulfur.

The layer 3 is obtained at the end of the annealing step.

FIG. 2 illustrates another step of the method in which holes 4 are formed in the stack made up of the layer 2 of conductive material and the absorbing layer 3.

Each hole has a surface area comprised between 0.005 mm² and 0.2 mm², and the total surface area occupied by the holes is comprised between 5% and 95% of the total surface area of the substrate.

Thus, these holes are small enough to be invisible to the human eye, at a distance from the panel of approximately several tens of centimeters.

These holes 4 can be made using known methods, like those described in document U.S. Pat. No. 7,795,067 or GB-2,472,608. These holes can be made using any other type of method.

The holes 4 can also be made via a method using a mask.

This mask can be deposited on the substrate 2 before the deposition of the layers 2 and 3 and then forms a positive stencil for the holes 4. After the deposition of the layers 2 and 3, the mask is removed, in particular by chemical etching, taking the part of the thin layers with which it is covered with it, those deposited directly on the substrate staying in place.

FIG. 2 shows that these holes are not through holes. In other words, they do not pass through the substrate, which remains continuous after the formation of the holes.

The product illustrated in FIG. 2 constitutes an intermediate product that can be produced independently of the steps of the method that are carried out later.

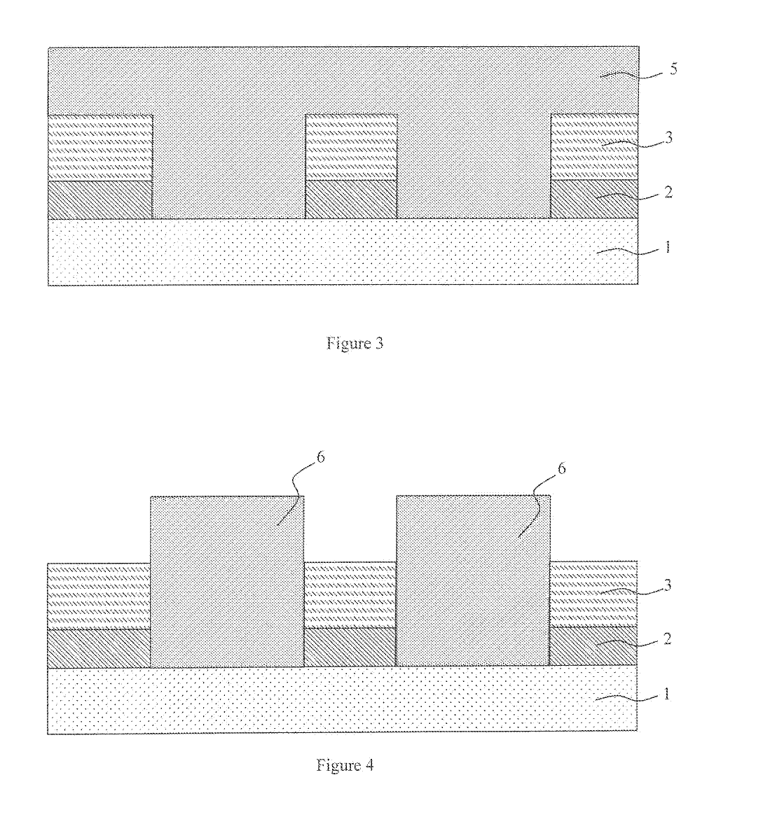

FIGS. 3 to 7 illustrate the other steps of the method that make it possible to obtain a semitransparent photovoltaic module.

In reference to FIG. 3, a layer of resin 5 is deposited on the entirety of the substrate so as to fill in the holes 4 and cover the absorbing layer 3.

In the illustrated example, the resin used is a negative photoresist resin, i.e., a photosensitive resin for which the part exposed to light becomes insoluble to the developer and where the part not exposed to light remains soluble.

A resin of this type is primarily made up of three components: an epoxy resin, an organic solvent making it possible to solubilize the resin and adjust the viscosity of the formulation, and a photo primer making it possible to prime the cationic polymerization.

Such resins are in particular described in the thesis by Feng Shi titled “Etudes et propriétés physico-chimie de surfaces microstructurées” [Physicochemical studies and properties of microstructure surfaces] (Institut National Polytechnique de Toulouse, 2006).

As an example, the resin marketed by the company Microchem under the name SU-8 can be used.

This layer 5 will for example be able to be deposited by spin coating or doctor blading.

Its thickness from the substrate 1 will typically be comprised between 1 μm and 100 μm.

Preferably, the thickness of the layer 5 will be greater than the thickness of the stack made up of the layer 2 and the layer 3, as illustrated in FIG. 3. However, in the context of the invention, it suffices for the thickness of the layer 5 to be greater than that of the layer 2.

After the deposition of this layer 5, a low-temperature annealing step is carried out.

The annealing temperature is comprised between 25 and 150° C., and preferably equal to 90° C.

The length of this annealing step is comprised between 1 and 60 min., and preferably equal to 30 min.

Once this annealing step has been done, the resin is next exposed through the substrate 1, using a lamp whose wavelength is comprised between 350 and 400 nm, and preferably 365 nm.

The layer 2 is opaque; it serves as a mask and therefore prevents light from reaching the resin present on the layer 3.

In practice, the layer 3 is also opaque, since it absorbs the light radiation.

Thus, only the resin present in the holes 4 will be cross-linked.

FIG. 4 illustrates another step in which the resin present on the absorbing layer 3 is removed using an appropriate solvent.

This removal is possible because the resin present on the absorbing layer 3 is not cross-linked.

As an example, the solvent could be PGMEA (polypropylene-glycol-methyl-ether-acetate).

FIG. 4 illustrates the stack obtained after removal of the non-cross-linked resin.

This product therefore has zones 6 made up of resin that is an insulating and transparent material.

The zones 6 protrudes relative to the plane defined by the absorbing layer 3.

The part of the zones 6 situated above this plane has a thickness comprised between 100 nm and 100 μm, depending on the thickness of the layer 5.

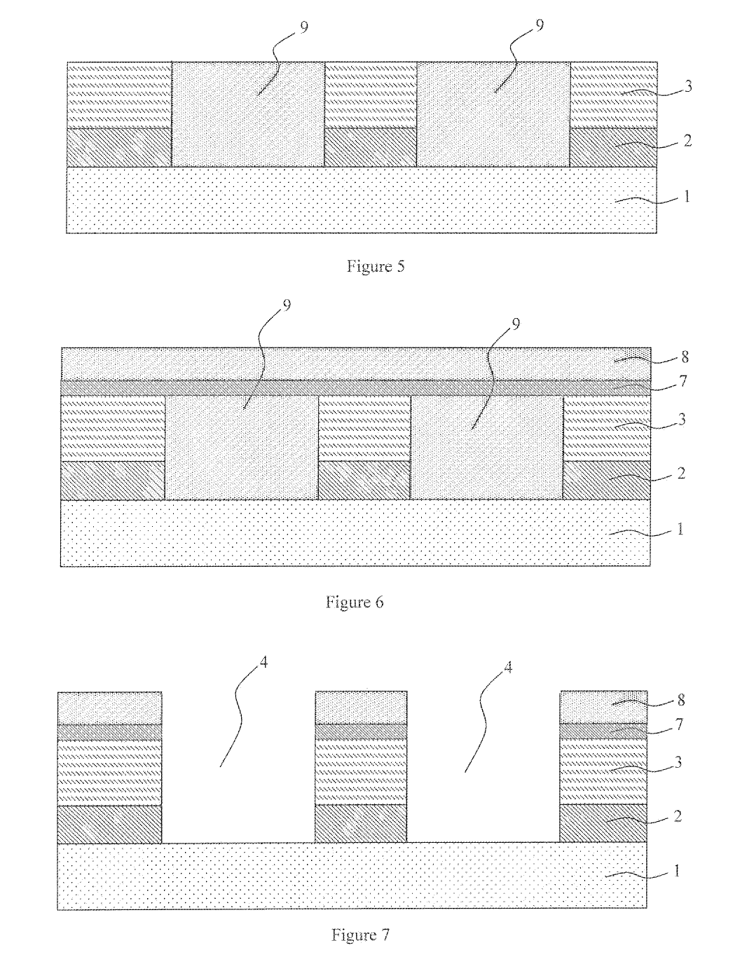

FIG. 5 illustrates another step of the method in which the part of the zones 6 situated above the absorbing layer has been eliminated, for example by mechanical polishing. It makes it possible to obtain zones 9 made of transparent and insulating material that therefore fills in the holes 4. This step is optional.

The last step of the method is illustrated in FIG. 6.

It first consists of depositing a buffer layer, i.e., a layer made up of a semiconductor material of type n.

The buffer layer 7 is a very thin layer whose thickness is generally comprised between 5 nm and 100 nm and is made from an n semiconductor material with a large forbidden energy gap. It therefore involves a layer having a high optical transmission level in the visible domain.

The material forming the layer 7 can have a base of cadmium sulfide (CdS) or zinc sulfide (ZnS).

This buffer layer can be deposited in particular by chemical bath, cathode sputtering or evaporation.

It preferably has a base of zinc sulfide (ZnS) and has a thickness preferably comprised between 5 and 100 nm.

This buffer layer 7 is optional.

Lastly, a transparent electrode 8 is deposited on the buffer layer 7, or directly on the absorbing layer if the buffer layer is omitted.

The electrode 8 is generally made from a conductive transparent oxide and has a high optical transmission level in the visible domain.

It preferably has a base of aluminum-doped ZnO and has a thickness preferably comprised between 100 nm and 1 μm.

Optionally, a layer of a transparent material can be deposited between the layers 7 and 8. It is preferably made from ZnO.

One then obtains the photovoltaic cell illustrated in FIG. 6. Owing to the presence of the zones 9 made up of a transparent material and appropriate distribution of these zones, this photovoltaic cell is semitransparent.

The layers 7 and 8 are continuous and planar, since the zones 9 are at the same level as the surface of the layer 3.

Furthermore, the presence of an insulating material in the holes 4 makes it possible to prevent, after formation of the holes, the layer 7 or 8 from coming into contact with the backside electrode 2. This makes it possible to avoid any short-circuit between the layer 7 or the layer 8 and the backside electrode 2, such as short-circuits greatly deteriorating the performance of the photovoltaic module.

To produce a photovoltaic module (not illustrated), it is necessary to carry out etching steps to ensure the monolithic interconnection of the various solar cells formed on the substrate. For simplification reasons, these steps are not illustrated in the various figures.

In practice, the etching step P1 takes place after the deposition of the layer 2, step P2 after the deposition of the layer 3 and the layer 7, and lastly, step P3 after the deposition of the layer 8.

Inasmuch as the resin used for the method according to the invention is highly transparent, while ensuring light transmission, in particular greater than 90%, the latter can be kept in the photovoltaic module, while allowing excellent light transmission.

However, it is possible to consider removing the resin present in the holes 4 to increase the optical transmission rate.

This resin removal will take place after depositing the layers 7 and 8.

This removal of the cross-linked resin will be done using a solvent such as NMP (N-Methyl-2-Pyrrolidone).

Access to the zones 9 made from resin should first be arranged.

To that end, it is preferable, before depositing the layers 7 and 8, not to have cross-linked the excess resin situated in the extension of the holes above the absorbing layer 3, i.e., to be in the case illustrated in FIG. 4. Indeed, in that case, the excess resin causes a localized rupture of the layers 7 and 8 during the deposition thereof, which allows the solvent to reach the resin.

The removal of the cross-linked resin present in the holes 4 also causes the lift-off of the layers 7 and 8 situated in the extension of the holes.

The obtained stack is illustrated in FIG. 7. Thus, the holes 4 are formed in the entirety of the stack and not only in the layers 2 and 3.

Once the resin is removed, the zones 9 are empty zones or zones without any material, the air constituting an insulator.

The reference signs inserted after the technical features appearing in the claims are intended only to facilitate the understanding of the latter and cannot limit their scope.

1. A method for obtaining a photovoltaic module including a plurality of photovoltaic cells in a thin layer structure, comprising:
producing an intermediate product by depositing a layer of a conductive material on the entirety of a substrate, forming an absorbing layer on this layer of conductive material, and producing holes through the stack formed by the layer of conductive material and the absorbing layer, the layer of conducting material forming the backside electrode,
depositing an insulating transparent material in the holes of the intermediate product, the absorbing layer not having this material, and
depositing a layer forming the front side electrode on the entirety of the obtained product.

2. The method according to claim 1, wherein, during the step for producing an intermediate product, the holes have a section with a surface area comprised between 0.005 mm² and 0.2 mm², and the total surface area occupied by the holes is comprised between 5% and 95% of the total surface area of the substrate.

3. The method according to claim 1, wherein the holes are made using a mechanical or chemical method, optionally involving a mask.

4. The method according to claim 1, wherein the step for depositing an insulating and transparent material in the holes of the intermediate product comprises:
depositing a resin on the entirety of the substrate to cover the absorbing layer and fill in the holes of the intermediate product,
cross-linking the resin present in the holes, and
eliminating the non-cross-linked resin present on the absorbing layer.

5. The method according to claim 4, wherein the resin is a negative photoresist resin that is first subjected to an annealing step before being exposed through the substrate, the layer forming a mask.

6. The method according to claim 1, comprising a step for depositing a buffer layer before depositing the layer forming the front side electrode.

7. The method according to claim 1, wherein after depositing the layer forming the front side electrode and any buffer layer, the cross-linked resin can be eliminated through the action of a solvent.

8. A semitransparent photovoltaic module comprising a plurality of photovoltaic cells connected in series on a shared substrate and comprising a front side electrode and a backside electrode, in contact with said substrate and spaced away from the front side electrode by at least one absorbing layer, in which the stack formed by the backside electrode and the absorbing layer comprises zones that are either empty, or made from an insulating and transparent material, the front side electrode forming a continuous layer.

9. The module according to claim 8, wherein the insulating material is a cross-linked transparent resin.

10. The module according to claim 8, wherein these zones have a section whereof the surface area is comprised between 0.005 mm² and 0.2 mm², and represents between about 5% and 95% of the total surface area of the substrate.

11. The module according to claim 8, comprising a buffer layer between the absorbing layer and front side electrode.

12. The module according to claim 8, wherein the buffer layer is a continuous layer.

13. The module according to claim 8, wherein the backside electrode is made from a metal material, in particular molybdenum, or from a conductive transparent oxide, in particular an aluminum-doped zinc oxide.

14. An intermediate product for obtaining a photovoltaic module according to claim 8, made up, on a substrate, of a stack formed by a layer of conductive material and an absorbing layer and that includes holes crossing through it.
